(19) United States
(12) Patent Application Publication
(10) Pub. No.: US 2010/0187572 A1
(43) Pub. Date: Jul. 29, 2010

(54) SUSPENDED MONO-CRYSTALLINE STRUCTURE AND METHOD OF FABRICATION FROM A HETEROEPITAXIAL LAYER

(76) Inventors: Hans S. Cho, Palo Alto, CA (US); Theodore I. Kamins, Palo Alto, CA (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/360,079

(22) Filed: Jan. 26, 2009

(51) Int. Cl. H01L 29/267; H01L 21/20

(52) U.S. Cl. 257/200; 438/478; 257/E21.09; 257/E29.081

(57) ABSTRACT

Methods of fabricating a suspended mono-crystalline structure use annealing to induce surface migration and cause a surface transformation to produce the suspended mono-crystalline structure above a cavity from a heteroepitaxial layer provided on a crystalline substrate. The methods include forming a three dimensional (3-D) structure in the heteroepitaxial layer where the 3-D structure includes high aspect ratio elements. The 3-D structure is annealed at a temperature below a melting point of the heteroepitaxial layer. The suspended mono-crystalline structure may be a portion of a semiconductor-on-nothing (SON) substrate.

### CROSS-REFERENCE TO RELATED APPLICATIONS

N/A

### STATEMENT REGARDING FEDERALLY SPONSORED RESEARCH OR DEVELOPMENT

N/A

### BACKGROUND

1. Technical Field

The invention relates to semiconductor fabrication and semiconductor devices. In particular, the invention relates to mono-crystalline structures in semiconductor devices.

2. Description of Related Art

Epitaxy or more generally epitaxial deposition represents a nearly indispensible step in the fabrication of many modern semiconductor devices. Epitaxial deposition may be used to create mono-crystalline layers of high quality crystalline films with ultra-high purity. For example, silicon (Si) epitaxy is often used to provide an ultra-pure layer of Si crystal on an underlying Si wafer. The ultra-pure Si layer is then used as a layer for realizing various devices through additional processing steps. Epitaxy is also a principal means for realizing mono-crystalline layers or films comprising materials and compositions not otherwise readily available in crystalline form. In particular, many devices including, but not limited to, devices fabricated from certain compound semiconductors (e.g., III-V and II-VI compound semiconductors), would not be practical without epitaxial deposition.

In general, epitaxy involves the deposition of a mono-crystalline layer or layers onto a surface of mono-crystalline substrate by one or more of several means. The epitaxially deposited mono-crystalline layer takes on lattice structure and lattice orientation of the underlying substrate on which the epitaxial deposition is performed. Homoepitaxy typically refers to the epitaxial deposition of a layer comprising the same material and composition as the substrate. On the other hand, the term ‘heteroepitaxy’ refers the epitaxial deposition of a mono-crystalline layer on a crystalline substrate where the deposited mono-crystalline layer comprises one or both of a material and a composition that is dissimilar to that of the crystalline substrate. There is considerable interest in heteroepitaxy and its use in producing heteroepitaxial layers, especially with respect to the production of complex, multi-functional devices (e.g., integrated electronic and photonic devices) as well as in the area of high efficiency solar cells and related optoelectronic devices.

Unfortunately, heteroepitaxial deposition often produces mono-crystalline layers of material that are less than ideal for use in realizing high-performance devices. In particular, a mismatch between a lattice constant of the crystalline substrate and the heteroepitaxial layer deposited on the substrate often exists. Such a ‘lattice mismatch’ introduces elastic strain in the heteroepitaxial layer that ultimately results in the formation of misfit and threading dislocations or simply ‘lattice defects’ in the heteroepitaxial layer. These lattice defects adversely affect the electrical properties of the heteroepitaxial layer, in part, by trapping charges at dangling bonds, thereby degrading current flow within the heteroepitaxial layer. Further, the lattice defects are often associated with or produce unacceptably high leakage currents in an OFF state of a device (e.g., diode junctions) fabricated in the heteroepitaxial layer. Such lattice defects due to the lattice mismatch between the heteroepitaxial layer and the underlying substrate have often frustrated the adoption of a wide variety of otherwise attractive material combinations for various electronic, photonic and mixed use applications.

In addition to providing high quality heteroepitaxial layers, there is great interest in forming faster devices and devices that exhibit lower-leakage by reducing a capacitance between a layer or layers of the device and a supporting substrate. An exemplary structure that may reduce these detrimental effects is achieved by placing an insulator between the device layers and the supporting substrate. The insulator ideally has both a low relative permittivity and a high resistivity. For example, in silicon-based devices a layer or layers of silicon dioxide (SiO₂) are often used as the insulator because of the comparatively lower relative permittivity (˜4) and a relatively high resistivity of such SiO₂ layers. However, even the relatively lower permittivity of solid-state material layers such as an oxide (e.g., SiO₂) may still limit high-performance devices. In some instances, an insulator with even lower permittivity is desirable between the device layers and the substrate.

To achieve a lower permittivity than is afforded by an oxide layer, a semiconductor layer may be suspended above a substrate at a finite spacing with either an ambient gas or a vacuum filling the finite spacing. An ambient gas or vacuum filled space provides an insulator with significantly lower, and in the case of a vacuum an absolute lowest permittivity, as well as a relatively high resistivity. Conventionally, such a suspended semiconductor layer may be provided by depositing a polycrystalline layer (e.g., polycrystalline silicon) over an oxide layer on the supporting substrate. The oxide layer acts as a sacrificial layer that is subsequently be removed to yield a polycrystalline suspended semiconductor layer. Although a suspended polycrystalline semiconductor layer may be adequate for some applications, it is not suitable for many high-performance devices. Such high-performance devices generally require a single-crystal layer which cannot be provided using a sacrificial oxide.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1 illustrates a flow chart of a method of fabricating a suspended mono-crystalline structure, according to an embodiment of the present invention.

FIG. 2A illustrates a cross sectional view of a heteroepitaxial layer on a crystalline substrate, according to an embodiment of the present invention.

FIG. 2B illustrates a cross sectional view of a three dimensional (3-D) structure formed in the heteroepitaxial layer illustrated in FIG. 2A, according to an embodiment of the present invention.

FIG. 2C illustrates cross sectional views of the 3-D structure illustrated in FIG. 2B during annealing, according to an embodiment of the present invention.

FIG. 2D illustrates a cross sectional view of a suspended mono-crystalline structure after annealing, according to an embodiment of the present invention.

FIG. 2E illustrates a cross sectional view of the suspended mono-crystalline structure after annealing, according to another embodiment of the present invention.

FIG. 3A illustrates a cross sectional view of a three dimensional (3-D) structure formed in the heteroepitaxial layer illustrated in FIG. 2A, according to another embodiment of the present invention.

FIG. 3B illustrates a cross sectional view of a suspended mono-crystalline structure resulting from the 3-D structure illustrated in FIG. 3A, according to an embodiment of the present invention.

FIG. 4A illustrates a perspective view of a 3-D structure formed in a heteroepitaxial layer, according to an embodiment of the present invention.

FIG. 4B illustrates a perspective view of a suspended mono-crystalline structure resulting from annealing the 3-D structure illustrated in FIG. 4A, according to an embodiment of the present invention.

FIG. 5A illustrates a perspective view of a 3-D structure formed in a heteroepitaxial layer, according to another embodiment of the present invention.

FIG. 5B illustrates a perspective view of a suspended mono-crystalline structure resulting from annealing the 3-D structure illustrated in FIG. 5A, according to an embodiment of the present invention.

FIG. 6A illustrates a perspective view of a 3-D structure formed in a heteroepitaxial layer, according to another embodiment of the present invention.

FIG. 6B illustrates a perspective view of a suspended mono-crystalline structure resulting from annealing the 3-D structure illustrated in FIG. 6A, according to an embodiment of the present invention.

FIG. 7A illustrates a perspective view of a 3-D structure formed in a heteroepitaxial layer, according to another embodiment of the present invention.

FIG. 7B illustrates a perspective view of a suspended mono-crystalline structure resulting from annealing the 3-D structure illustrated in FIG. 7A, according to an embodiment of the present invention.

Certain embodiments of the present invention have other features that are one of in addition to and in lieu of the features illustrated in the above-referenced figures. These and other features of the invention are detailed below with reference to the preceding drawings.

### DETAILED DESCRIPTION

Embodiments of the present invention facilitate realizing a mono-crystalline structure suspended above an underlying crystalline substrate. For example, embodiments of the present invention may provide a so-called ‘semiconductor-on-nothing’ structure. The suspended mono-crystalline structure comprises a single crystal of a crystalline material and is formed from a heteroepitaxial layer that has an epitaxial connection with the underlying crystalline substrate, according to the present invention. In some embodiments, the suspended mono-crystalline structure may have fewer lattice defects than the heteroepitaxial layer from which the suspended mono-crystalline structure is formed. In particular, a suspended portion of the heteroepitaxial layer that forms the suspended mono-crystalline structure may have a lower lattice defect density than portions of the heteroepitaxial layer that are not suspended, according to some embodiments.

As noted above, the suspended mono-crystalline structure is formed from a heteroepitaxial layer on the underlying crystalline substrate. In general, the heteroepitaxial layer may comprise any material that may be deposited or grown as an epitaxial film or layer on the crystalline substrate, according to embodiments of the present invention. The heteroepitaxial layer is ‘epitaxial’ having a direct crystallographic connection with the underlying crystalline substrate. However, by definition of the term ‘heteroepitaxial’ as employed herein, a material or a material composition of the heteroepitaxial layer differs from a material or a material composition of the underlying crystalline substrate. In some embodiments, a melting point of the heteroepitaxial layer material is less than a melting point of the crystalline substrate material. In some of these embodiments, the melting points may differ by more than about 100-200 degrees Celsius (C.).

The heteroepitaxial layer may be deposited or grown on the substrate using virtually any method that produces an epitaxial layer. Exemplary means for providing the heteroepitaxial layer directly on the substrate include, but not limited to, chemical vapor deposition (CVD), vapor-phase epitaxy (VPE), liquid-phase epitaxy (LPE), and molecular beam epitaxy (MBE). In addition, the heteroepitaxial layer may be provided indirectly. For example, epitaxial solid-phase crystallization of an amorphous layer deposited on the crystalline substrate that uses the crystalline substrate as a seed crystal may be employed to indirectly provide the heteroepitaxial layer, according to various embodiments.

As such, the term ‘suspended mono-crystalline structure’ used herein is defined to mean a crystalline structure comprising a single crystal that is formed from a precursor layer comprising the heteroepitaxial layer. By definition, the suspended mono-crystalline structure which is formed from the heteroepitaxial layer comprises a material or a material composition that differs from the material or the material composition of the substrate. The suspended mono-crystalline structure is suspended above an open space or a cavity that physically separates it from either the crystalline substrate itself or another portion of the heteroepitaxial layer on a surface of the crystalline substrate. A lateral extent of the suspended mono-crystalline structure is limited, in various embodiments.

Further by definition, the suspended mono-crystalline structure comprises a single crystal of the heteroepitaxial layer material. That is, a crystal lattice of the suspended mono-crystalline structure has effectively the same orientation throughout its extent (i.e., is effectively a single crystal grain). The terms ‘crystalline’ ‘mono-crystalline’ and ‘single crystal’ are employed herein to distinguish over materials that have multiple crystal grains such as polycrystalline or microcrystalline materials or that are amorphous materials. Moreover, unlike the precursor heteroepitaxial layer, the suspended mono-crystalline structure may not maintain a direct crystallographic connection to the underlying crystalline substrate, in some embodiments. For example, the direct crystallographic connection may be lost or at least modified over at least a portion of an area of the suspended mono-crystalline structure as a result of thermal processing used to form the suspended mono-crystalline structure from the heteroepitaxial layer. Thus, while the suspended mono-crystalline structure comprises a single crystal, it need not be epitaxially connected to the crystalline substrate, in some embodiments. It is with this definition of the term ‘suspended mono-crystalline structure’ that the following description is provided.

In some embodiments, the heteroepitaxial layer and suspended mono-crystalline structure formed therefrom may comprise a first semiconductor. Examples of semiconductor materials applicable to forming the heteroepitaxial layer include, but are not limited to, silicon (Si), gallium arsenide (GaAs), indium phosphide (InP), aluminum gallium indium phosphide (AlGaInP), cadmium telluride (CdTe), zinc telluride (ZnTe), gallium nitride (GaN), germanium (Ge) and silicon germanium (SiGe). In some embodiments, the underlying crystalline substrate may be a crystalline insulator. Example materials or material compositions of the crystalline substrate include, but are not limited to, sapphire (single crystal Al₂O₃), quartz (single crystal SiO₂), silicon carbide (SiC), and diamond. In another embodiment, the crystalline substrate may comprise a crystalline conductor (e.g., a crystalline metal).

In other embodiments, the crystalline substrate may comprise a second semiconductor. By definition, the second semiconductor is different in terms of a constituent material or material composition from the first semiconductor of the heteroepitaxial layer. For example, the heteroepitaxial layer may comprise Ge while the crystalline substrate comprises Si. In another example, the crystalline substrate comprises Si and the heteroepitaxial layer comprises GaAs. In yet another example, the crystalline substrate may comprise aluminum nitride (AlN) or gallium nitride (GaN), while the heteroepitaxial layer comprises Si or zinc oxide (ZnO). In yet another example, the crystalline substrate may comprise alloys of cadmium telluride (CdTe) or zinc telluride (ZnTe), while the heteroepitaxial layer comprises Ge.

In another embodiment, the heteroepitaxial layer comprises a crystalline material other than a semiconductor (e.g., an insulator or a conductor) while the crystalline substrate comprises a semiconductor. In some embodiments, the crystalline substrate itself may be a ‘virtual substrate’ that is grown or bonded onto another substrate. In general, for embodiments of the present invention in which one or both of the heteroepitaxial layer and the crystalline substrate comprises a semiconductor, effectively any semiconductor (e.g., including compound semiconductors) that can be either epitaxially deposited or formed as the crystalline substrate may be employed. For example, the semiconductor or semiconductors may comprise a semiconductor selected from group IV (e.g., Si or Ge) or a compound semiconductor such as, but not limited to a III-V compound semiconductor and a II-VI semiconductor. In other embodiments, neither the heteroepitaxial layer nor the crystalline substrate comprises a semiconductor.

In some embodiments, a lattice of the heteroepitaxial layer may not align precisely with or match a lattice of the crystalline substrate. In such embodiments, the heteroepitaxial layer may exhibit lattice defects as a result of lattice mismatch at a common interface of the heteroepitaxial layer and the crystalline substrate. The lattice defects may be a result of elastic strain that develops at the interface, for example. Depending on a crystal orientation of the crystalline substrate, the lattice defects present in the heteroepitaxial layer may extend or propagate through an entire thickness of the heteroepitaxial layer. For example, a Ge-based heteroepitaxial layer grown on a (001)-oriented Si wafer will generally exhibit lattice defects. A (001)-oriented Si wafer is often commonly or interchangeably referred to as a (100) Si wafer.

Embodiments of the present invention employ high-temperature annealing to produce a surface deformation or a surface transformation of the heteroepitaxial layer. The surface transformation occurs through atomic level surface diffusion or surface migration within a crystal lattice of the crystalline material of the heteroepitaxial layer. The high-temperature annealing that produces surface migration is performed at a temperature below a melting point of the crystalline material, according to various embodiments. Therefore, high-temperature annealing, often referred to as simply ‘annealing’ for the purpose of discussion herein, is distinguished from processes that affect changes in a crystalline lattice of a material by melting and recrystallizing the material. Annealing-based surface migration that leads to surface transformation, also variously referred to as self-organizing recrystallization and self-organized atomic migration, is described for homogeneous semiconductors (e.g., bulk silicon) by Sato et al., U.S. Pat. Nos. 6,630,714, 7,019,364, Yang et al., U.S. Pat. No. 7,157,350, and Forbes et al., U.S. Pat. No. 6,929,984. Additional discussion regarding surface migration applied to crystalline bulk silicon (bulk-Si) can be found in Sato et al., “Fabrication of silicon-on-nothing structure by substrate engineering using the empty-space-in-silicon formation technique,” Jap. J. Applied Physics, Vol. 43, No. 1, 2004, pp. 12-18 (hereinafter ‘Sato et al.’), and in Kuribayashi et al., “Shape transformation of silicon trenches during hydrogen annealing,” J. Vac. Sci. Technol. A, Vol. 21, No. 4, July-August 2003, pp. 1279-1283 (hereinafter ‘Kuribayashi et al.’).

Embodiments of the present invention apply the annealing to a three dimensional (3-D) structure formed in the heteroepitaxial layer. In some embodiments, the 3-D structure may be formed in a portion of the underlying substrate as well as in the heteroepitaxial layer. In various embodiments, the 3-D structure comprises a plurality of high aspect ratio elements having a variety of shapes. By definition herein, a ‘high aspect ratio’ element is an element (e.g., a hole, a post, a trench, etc.) of the 3-D structure that is generally taller (or equivalently deeper) than it is wide. In some embodiments, the high aspect ratio element may have a height that is significantly greater than two times (2×) a width of the element. For example, a hole (i.e., an element) formed in the heteroepitaxial layer is considered to be a high aspect ratio element when a depth of the hole is greater than twice a diameter of the hole. In another example, a trench formed in the heteroepitaxial layer is considered to be a high aspect ratio element when a depth of the trench is greater than 2 times a width across the trench. In another example, the hole or the trench may be more than about 4 times as deep as it is wide. Thus, a high aspect ratio element may have a height-to-width or aspect ratio that is greater than about 2:1 and may be greater than about 4:1, in various embodiments. Other examples of high aspect ratio elements, as well as guidelines for spacing between the elements, may be found in Sato et al., Kuribayashi et al., as well as the various U.S. patents cited above (e.g., U.S. Pat. No. 6,929,984 to Forbes et al.).

During the high-temperature annealing, atoms in a surface of the crystalline material migrate in a manner that tends to reduce an overall energy state associated with a shape of the 3-D structure. For example, sharp corners present in the 3-D structures tend to become rounded by the annealing. In another example, narrow, high aspect ratio elements within the 3-D structures tend to become less narrow and may even bulge to a point of touching and ultimately fusing with adjacent elements, as a result of the surface migration. Touching and fusing between adjacent elements eventually produces the suspended mono-crystalline structure and the associated cavity, according to embodiments of the present invention. An intersection between a top wall of the cavity and a side wall of the cavity is rounded and exhibits a finite radius of curvature as a result of the surface migration, according to various embodiments. A minimum value of the finite radius of curvature is related to a resolution of a means used to form the elements of the 3-D structure.

The finite radius of curvature produced by annealing may be about the radius of the spherical cavities or voids formed by a single element, in some embodiments. For example, an edge or wall at an end of a plate-shaped cavity is a void in the heteroepitaxial layer formed out of an open space provided by the single element (e.g., a hole). If the element is a hole and the hole is about 500 nm in diameter and about 3 um (microns) deep (i.e., aspect ratio=6:1), an effective upper bound for a volume of a cavity formed from such hole is about 0.589 μm³, for example. Assuming that the cavity formed by the exemplary hole is perfectly spherical, a diameter of the spherical cavity is less than about 1.047 microns. In an example that employed an array of such exemplary holes but with the holes being much deeper (e.g., providing an aspect ratio of 20:1) so that a plate-shaped or planar suspended mono-crystalline structure is formed by annealing before voids become fully spherical, a radius of curvature may be somewhat larger than the radius of the initial hole. Thus, a rule of thumb may be that the finite radius of curvature at an edge of a cavity (i.e., between a roof and a wall of the cavity) may be at least a radius of the hole (or equivalently a width of the trench or space of an element) used in forming the cavity.

A shape and specific dimensions of the elements (e.g., holes, trenches, posts, etc.) and spaces between the elements within the 3-D structure prior to the annealing are generally determined by the desired final configuration of the suspended mono-crystalline structure after the annealing. In general, surface transformation or deformation pathways, which ultimately determine the final configuration, are dependent on the initial geometries of the 3-D structure elements. For example, if the elements are too wide relative to their depth, the deformation could simply result in a rounded, flattened structure in which openings or ‘mouths’ of the elements remain open. To obtain a suspended mono-crystalline structure in a configuration of a continuous suspended film from an array of holes, for example, the holes generally need to be small enough for the mouths of the holes to close during the annealing. Likewise, the holes need to be deep enough so that the holes can evolve into voids under the fused, suspended material at the top that forms the suspended mono-crystalline structure.

Experimentally, an exemplary aspect ratio (i.e., depth-to-width ratio) of holes in an array that may be used to form a suspended film configuration after annealing has been found to be above 4:1 in the case of a uniform Si-based suspended mono-crystalline structure, for example. As for the spacing between the exemplary holes, in effectively any material system, it is generally the case that the smaller the spacing, the more likely the cavities that evolve from holes are to merge into a single cavity under the suspended mono-crystalline structure during annealing. An optimal spacing to achieve merging of cavities is also a function of the hole depth and width.

For example, a roughly spherical cavity that evolves from an exemplary hole has a volume and diameter determined or limited by an initial volume of the hole. If the diameter of the cavity is significantly smaller than the spacing of the initial holes (e.g., nearest-neighbor distance or center-to-center), it is likely the cavities will not merge. In the example of an array of 500 nm diameter holes with depths of about 3 microns (μm) (i.e., an aspect ratio of 6:1) described above, an upper bound for the volume of a void formed from a single such hole is approximately 0.589 μm³. Assuming that the cavity formed from a single hole is perfectly spherical, the diameter of this cavity is less than about 1.047 microns, and the spacing between initial holes can be practically set at a value that is safely below this amount (e.g., 900 nm) to insure that the cavities will merge, for example.

In various embodiments, the mono-crystalline structure comprises fewer lattice defects than the heteroepitaxial layer from which it is formed. In particular, as the annealing-produced surface transformation of the 3-D structure proceeds, lattice defects due to the lattice mismatch present in the portion of the heteroepitaxial layer within the 3-D structure are effectively mitigated. The mitigation may occur from a combination of mechanisms. For example, a cavity or cavities formed below the forming suspended mono-crystalline structure may terminate (i.e., interrupt) lattice defects originating from the crystalline substrate/heteroepitaxial layer interface. In general, the larger the cavity, the more lattice defects are terminated.

In addition, surface migration mitigates lattice defects in material that is transferred and reconstituted into the mono-crystalline structure during annealing. In particular, the suspended mono-crystalline structure is physically decoupled from the crystalline substrate by annealing with the formation of the cavity or cavities. Moreover, heteroepitaxial layer material that was formerly located where the cavities are formed may be transferred and reconstituted into the suspended mono-crystalline structure. The transferred and reconstituted material is added to the suspended mono-crystalline structure in a form that is effectively free of lattice defects during annealing. Finally, remaining defects in the suspended mono-crystalline structure may be mitigated by bulk diffusion therewith during annealing. The newly constituted suspended mono-crystalline structure following annealing is bounded at a top surface and a bottom surface (and in some embodiments on two side surfaces) effectively by empty space. Any line or planar lattice defect in a crystal structure of the suspended mono-crystalline structure will be almost fully annihilated after annealing, for example.

In some embodiments, annealing is performed in a hydrogen ambient atmosphere. As used herein, a hydrogen ambient atmosphere, or simply ‘hydrogen ambient’, is one in which a partial pressure of hydrogen is sufficient to facilitate surface migration of atoms (e.g., Ge atoms), as described below. In some embodiments, the hydrogen ambient atmosphere is a reduced-pressure hydrogen ambient. The hydrogen ambient may be at a pressure of about 10 Torr, for example. The hydrogen provided by the hydrogen ambient may promote or facilitate surface migration of the atoms in the 3-D structure formed in the heteroepitaxial layer by breaking surface crystal bonds through repeated adsorption and ‘desorption’. Further, the presence of hydrogen in the hydrogen ambient may minimize formation of oxides on the surface of the forming suspended mono-crystalline structure. Such oxides might interfere with surface migration and the resulting surface transformation and are potentially detrimental. In some embodiments, a cleaning step is performed in which a surface of the heteroepitaxial layer is cleansed of effectively all oxide and oxide-forming impurities. After cleaning, a surrounding atmosphere may be purged of oxygen, water vapor, and other oxidizing gases, before annealing, for example.

For example, the hydrogen ambient may be used with a Ge-based heteroepitaxial layer and 3-D structure to facilitate surface migration. The hydrogen ambient may be employed at an annealing temperature of between about 650 degrees C. and 850 degrees C., for example. The hydrogen ambient may be employed with an Si-based heteroepitaxial structure in another example, albeit at a higher temperature (e.g., 1000 degrees C.).

In some embodiments, the employed hydrogen ambient effectively comprises pure hydrogen (H₂) gas. In other embodiments, a hydrogen ambient comprising an inert gas (nitrogen, argon, helium, etc.) or a mixture of hydrogen and an inert gas may be employed. For example, the H₂ in the hydrogen gas may be at a concentration of between about 1% and just below 100% with a remaining gas being the inert gas. For example, a mixture of this type may be used to prevent overshooting a desired terminal configuration of the suspended mono-crystalline structure. For example, the presence of the inert gas may effectively increase a tolerance window of the annealing to account for deviations in an anneal time or local structural non-uniformities (e.g., 3-D structure patterning irregularities, etc.) In some embodiments that employ an inert gas—hydrogen ambient, a ratio of H₂ to the inert gas may be varied during annealing. For example, a hydrogen ambient with approximately 100% H₂ may be used at a beginning of the annealing. The concentration of H₂ may be reduced as annealing proceeds to effectively retard the surface transformation as the suspended mono-crystalline structure nears a desired terminal configuration. In other embodiments, the annealing is performed in ultra-high vacuum. Ultra-high vacuum may be employed, similarly to hydrogen, to avoid unwanted oxidation, for example, when the hydrogen ambient is not used.

For simplicity herein, no distinction is made between the terms ‘layer’ and ‘layers’ unless such distinction is necessary for proper understanding. For example, a layer may comprise several distinct and separate layers and still be referred to herein as a ‘layer’ unless the presence of multiple layers is an important aspect of the discussion. Similarly, unless the difference is important for proper understanding, no distinction is made between a substrate and a substrate with layers formed on the surface or within the substrate. In particular, the crystalline substrate may comprise a substrate (i.e., either crystalline or non-crystalline) with a crystalline surface layer. Further, as used herein, the article ‘a’ is intended to have its ordinary meaning in the patent arts, namely ‘one or more’. For example, ‘a layer’ generally means one or more layers and as such, ‘the layer’ means ‘the layer(s)’ herein. Also, any reference herein to ‘top’, ‘bottom’, ‘upper’, ‘lower’, ‘up’, ‘down’, ‘left’ or ‘right’ is not intended to be a limitation herein. Moreover, examples herein are intended to be illustrative only and are presented for discussion purposes and not by way of limitation.

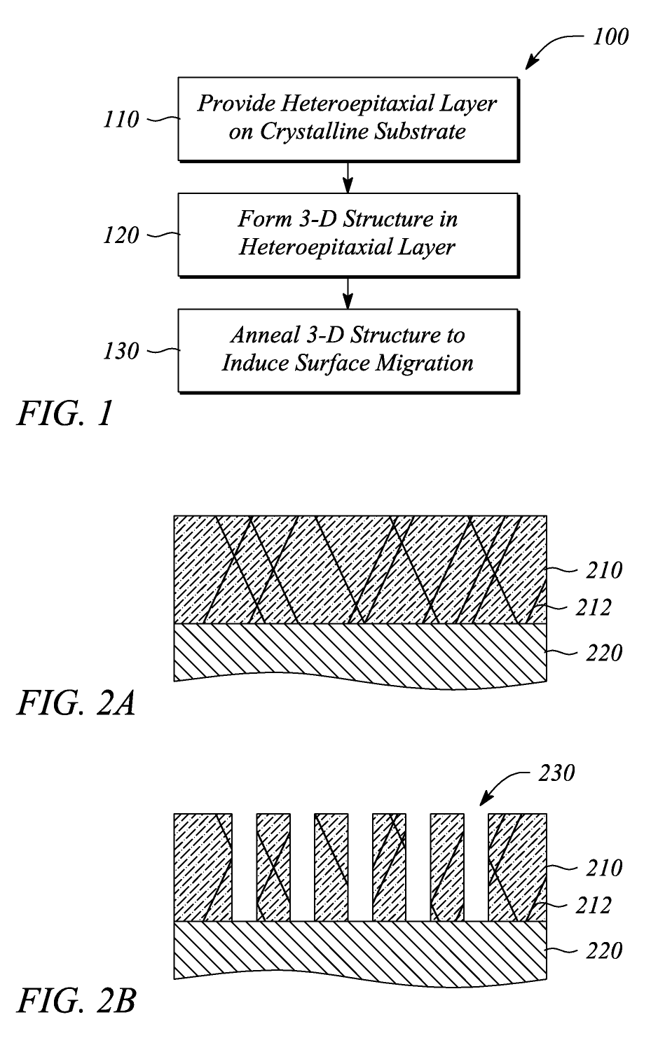

FIG. 1 illustrates a flow chart of a method 100 of fabricating a suspended mono-crystalline structure, according to an embodiment of the present invention. The suspended mono-crystalline structure fabricated according to the method 100 is a crystalline structure that is epitaxially connected to or epitaxially associated with an underlying crystalline substrate, by definition. In some embodiments, the suspended mono-crystalline structure comprises a semiconductor material. In some embodiments, both of the underlying crystalline substrate and the suspended mono-crystalline structure comprise semiconductor materials. In yet other embodiments, one or both of the suspended mono-crystalline structure and the underlying crystalline substrate are not semiconductors.

The fabricated suspended mono-crystalline structure is suspended above an open space or cavity. In some embodiments, the cavity separates the suspended mono-crystalline structure from the underlying substrate. In other embodiments, the cavity may be within a heteroepitaxial layer from which the heteroepitaxial structure is formed. In such embodiments, the cavity effectively separates the suspended mono-crystalline structure from an underlying portion of the heteroepitaxial layer that remains after the suspended mono-crystalline structure is formed.

In some embodiments, the suspended mono-crystalline structure may be a suspended film or layer that forms or acts as a roof or top wall of the cavity. In some of these embodiments, the cavity may be substantially closed or surrounded on all sides by material of the heteroepitaxial layer. In other embodiments, the cavity may be open at one or more places in a wall or walls of the cavity (e.g., at an edge or edges of the suspended mono-crystalline structure). For example, the suspended mono-crystalline structure may resemble a relatively wide, flat plate-like bridge that connects two opposing walls of a trench formed in the heteroepitaxial layer. In this example, the cavity may be open on two ends of the trench between the walls. In other embodiments, the suspended mono-crystalline structure may assume the form of a bar or a rod. The bar or rod may span between two walls, for example. In such embodiments, the cavity comprises an open space between the walls and below the rod that separates the rod from an underlying layer or material (e.g., the crystalline substrate).

As illustrated in FIG. 1, the method 100 of fabricating a suspended mono-crystalline structure comprises providing 110 a heteroepitaxial layer on a crystalline substrate. By definition herein, the heteroepitaxial layer comprises a crystalline material or a crystalline material composition that is different from a material or a material composition of the crystalline substrate. Further by definition, the heteroepitaxial layer has an epitaxial connection to the crystalline substrate at a mono-crystalline surface thereof. In some embodiments, there is a lattice mismatch between a crystal lattice of the heteroepitaxial layer and a crystal lattice of the crystalline substrate. The lattice mismatch may introduce lattice defects within the heteroepitaxial layer. For example, the crystalline substrate may comprise silicon (Si) and the heteroepitaxial layer may comprise germanium (Ge).

The heteroepitaxial layer on the crystalline substrate may be provided 110, by growing an epitaxial layer of a material of the heteroepitaxial layer on a surface of the crystalline substrate. For example, an epitaxial layer of Ge may be grown on a surface of the crystalline substrate. Any means for growing or otherwise forming a heteroepitaxial layer on the crystalline substrate may be employed. For example, the heteroepitaxial layer may be grown using one of molecular beam epitaxy (MBE) or vapor-phase epitaxy (VPE). The VPE-based epitaxial growth may use either reduced pressure chemical vapor deposition (RPCVD) or low pressure chemical vapor deposition (LPCVD), for example.

In some embodiments, a melting point of the heteroepitaxial layer is lower than a melting point of the crystalline substrate. In some embodiments, the heteroepitaxial layer melting point is much lower (e.g., 100-200 degrees C. or more) than the melting point of the crystalline substrate. In other embodiments, a melting point of the heteroepitaxial layer is not lower and may be about the same as the melting point of the crystalline substrate. In yet other embodiments, the melting point of the heteroepitaxial layer may exceed the melting point of the crystalline substrate.

For example, a heteroepitaxial layer comprising Ge has a melting point of about 938 degrees C. A Si-based crystalline substrate which has a melting point of about 1,414 degrees C. may be used as the crystalline substrate with such a Ge-based heteroepitaxial layer, for example. In another example, a GaAs-based heteroepitaxial layer having a melting point of about 1,238 degrees C. may be employed with a Si-based crystalline substrate. In yet another example, a Si-based heteroepitaxial layer may be used with a sapphire crystalline substrate which has a melting point of around 2,030-2,050 degrees C. Numerous other example combinations may be readily devised wherein the melting point of the heteroepitaxial layer is lower than the melting point of the substrate. All such combinations are within the scope of the present invention.

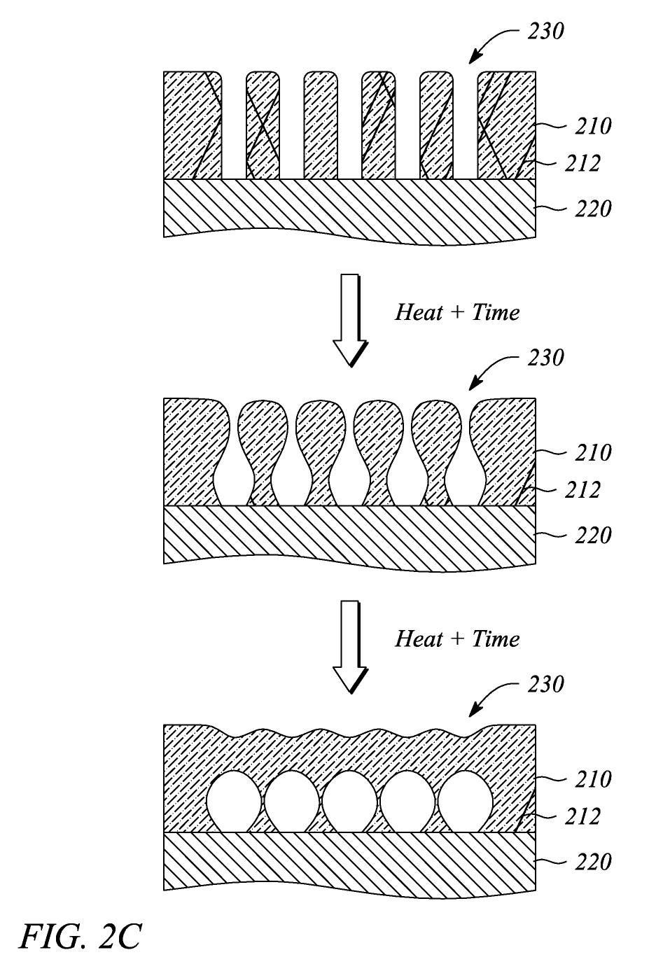

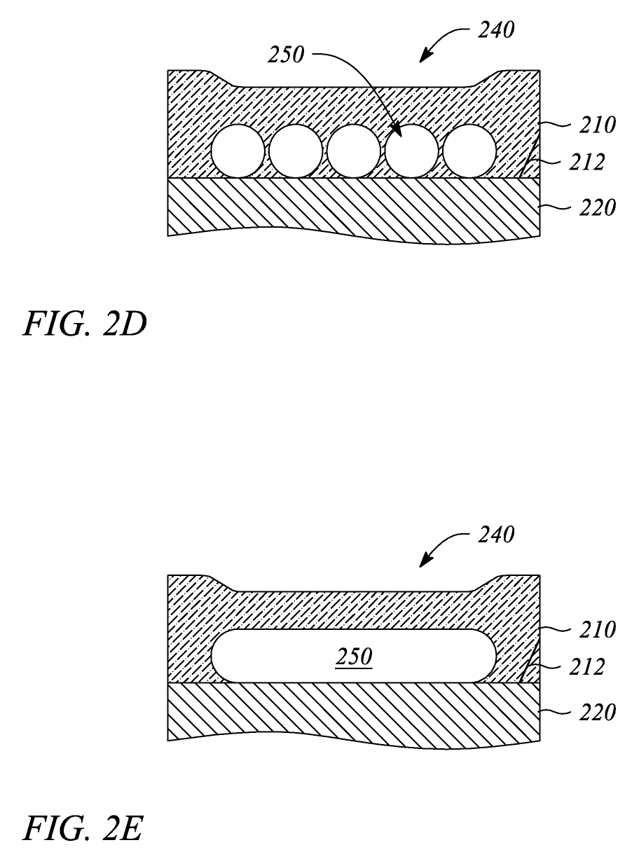

FIG. 2A illustrates a cross sectional view of a heteroepitaxial layer 210 on a crystalline substrate 220, according to an embodiment of the present invention. In particular, the heteroepitaxial layer 210 is illustrated on a top surface of the crystalline substrate 220. There may be a lattice mismatch between a lattice of the heteroepitaxial layer 210 and a lattice of the crystalline substrate 220. The lattice mismatch introduces lattice defects 212 in the heteroepitaxial layer 210. The heteroepitaxial layer 210 may comprise Ge, for example.

Referring again to FIG. 1, the method 100 of fabricating a suspended mono-crystalline structure further comprises forming 120 a three dimensional (3-D) structure in the heteroepitaxial layer. Forming 120 may comprise masking and subsequently etching the heteroepitaxial layer using one or more of a wet etching technique and a dry etching technique, according to various embodiments. For example, anisotropic etching using reactive ion etching (RIE) may be employed to form 120 the 3-D structure.

In another embodiment, the 3-D structure may be formed 120 by depositing a removable masking layer, such as silicon dioxide, and patterning the masking layer into high aspect ratio structures (e.g., pillars) using a conventional method. The patterned high aspect ratio structures are effectively a negative of a final pattern of spaces or voids in the 3-D structure. Forming 120 further comprises performing selective epitaxial growth of the heteroepitaxial material, seeded from the crystalline substrate, within the patterned high aspect ratio structures. Following epitaxial growth, the masking layer is removed. For example, the masking layer may be removed by selective chemical etching. Hydrogen fluoride (HF) may be used to selectively remove silicon dioxide, for example. Removal of the masking layer leaves behind the 3-D structure in the heteroepitaxial layer.

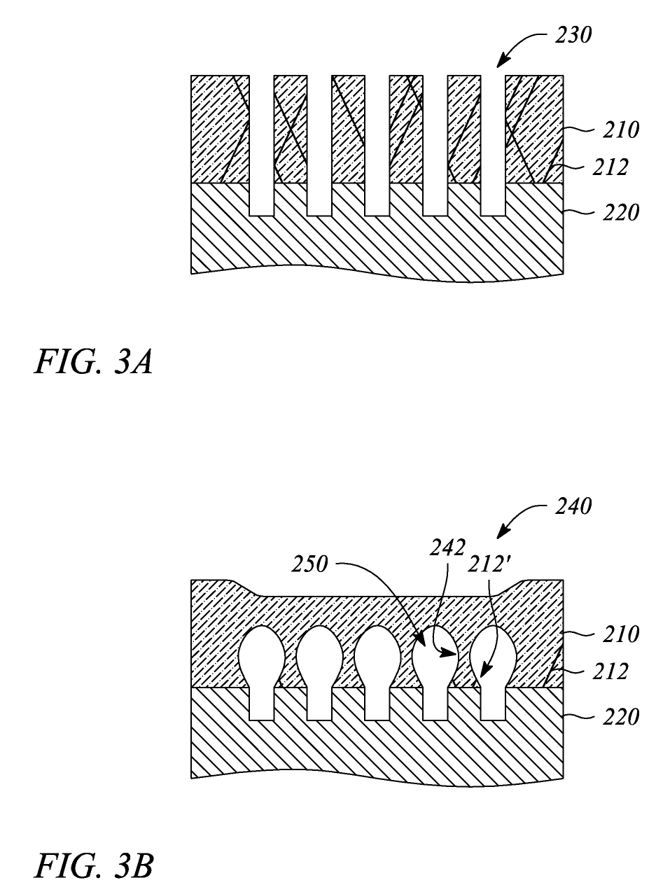

In some embodiments, the 3-D structure comprises high aspect ratio elements and therefore, is a high aspect ratio 3-D structure, by definition. In particular, the 3-D structure generally extends from a surface of the heteroepitaxial layer opposite the crystalline substrate toward the crystalline substrate. In some embodiments, the 3-D structure extends through an entire thickness of the heteroepitaxial layer. In some embodiments, the 3-D structure extends beyond the heteroepitaxial layer into a surface portion of the underlying crystalline substrate (e.g., see FIG. 3A, described below).

In various embodiments, the 3-D structure formed 120 in the heteroepitaxial layer may have elements that comprise one or more of holes, trenches and a wall or walls formed vertically in the heteroepitaxial layer. For example, the 3-D structure may comprise a relatively narrow wall spanning between two blocks of the heteroepitaxial layer. In another example, the 3-D structure may comprise a two dimensional (e.g., rectangular or circular) array of holes etched into the heteroepitaxial layer. In yet another example, the 3-D structure may comprise a plurality of parallel trenches formed in a surface of the heteroepitaxial layer. In some embodiments, a spacing between elements in the 3-D structure may be regular while in other embodiments the spacing may vary or be irregular. Individual elements within a given 3-D structure may also vary in size relative to one another.

FIG. 2B illustrates a cross sectional view of a three dimensional (3-D) structure 230 formed 120 in the heteroepitaxial layer 210 illustrated in FIG. 2A, according to an embodiment of the present invention. The 3-D structure 230 illustrated in FIG. 2B may represent either an array of holes or a plurality of parallel trenches viewed in cross section, for example. Further as illustrated, the 3-D structure 230 intercepts and terminates the lattice defects 212 present in the heteroepitaxial layer 210. In particular, walls of elements of the 3-D structure 230 intercept most of the lattice defects 212. Other ones of the lattice defects 212 are terminated by the surface of the heteroepitaxial layer 210, for example.

Again referring to FIG. 1, the method 100 of fabricating further comprises annealing 130 the 3-D structure. Annealing induces surface migration in the heteroepitaxial layer. Annealing 130 the 3-D structure to induce surface migration results in a surface transformation of the 3-D structure. The surface transformation produces the suspended mono-crystalline structure above a cavity.

Annealing 130 comprises exposing the heteroepitaxial layer with the 3-D structure formed 120 therein to a predetermined temperature for a predetermined period of time. The predetermined temperature is selected to be a temperature high enough to induce surface migration. In particular, the annealing temperature and predetermined time period are determined to achieve a desired amount of surface migration, as is described below in more detail. However, the annealing temperature is always selected to be less than or below a melting point of the heteroepitaxial layer.

For example, when the heteroepitaxial layer comprises Ge, annealing 130 may be performed in a temperature range from about 650 degrees C. to about 850 degrees C. In another example, an annealing temperature range extending up to about 900 degrees C. or just below the melting point of Ge (i.e., about 937 degrees C.) may be employed. The predetermined time period for annealing for the above example, may range from several minutes to one hour or even longer. Generally, longer time periods are used for lower annealing temperatures. For example, the predetermined annealing time period may be between about 3 minutes and about 5 minutes and the annealing temperature may be 800 degrees C. In another example, a one hour annealing time period may be employed with an annealing temperature of about 650 degrees C. In another example, an annealing temperature of about 700 degrees C. and an annealing time period of about 30 minutes is employed (e.g., for a Ge-based heteroepitaxial layer in a 10 Torr hydrogen ambient). In yet another example wherein the heteroepitaxial layer comprises Si, annealing 130 may be performed at about 1000 degrees C. for about 3-60 minutes. Variations in a combination of annealing temperature and time may be used to control an amount of surface migration, for example.

In some embodiments, a material of the crystalline substrate may be selected such that the melting point of the material is sufficiently greater than a melting point of the heteroepitaxial layer to prevent or at least minimize warping or other potentially deleterious effects on the crystalline substrate resulting from exposure to heating during high-temperature annealing. In some embodiments, the melting point differences may be on the order of about 100-200 degrees C. In other embodiments, the melting point differences may be greater than about 200 degrees C. For example, when an Si-based crystalline substrate is used with a Ge-based heteroepitaxial layer, the melting point difference is greater than about 400 degrees. Annealing a Ge-based heteroepitaxial layer at 850 degrees C. for from several minutes to an hour or more has been shown to have little or no lasting effect on such an exemplary underlying Si-based crystalline substrate, for example.

FIG. 2C illustrates a cross sectional view of the 3-D structure 230 illustrated in FIG. 2B during annealing 130, according to an embodiment of the present invention. In particular, FIG. 2C illustrates several (i.e., 3) stages of surface transformation that occur during annealing 130 through surface migration. In an initial stage illustrated at the top of FIG. 2C, surface migration has resulted in a general rounding of sharp corners present in the 3-D structure 230 illustrated in FIG. 2B. As annealing proceeds and surface migration continues, the surface transformation results in a widening of upper regions of solid portions of the 3-D structure 230, as is illustrated in the middle of FIG. 2C. The surface transformation resulting from the annealing-produced surface migration occurs in a manner that seeks to minimize a surface energy state of the 3-D structure 230. Finally, as illustrated at the bottom of FIG. 2C, the annealing-produced surface transformation of the 3-D structure 230 results in the fusing together of adjacent widened solid portions of the 3-D structure 230. Concomitant with the fusing is a formation of irregular shaped (e.g., vaulted) cavities between the fused, adjacent widened portions and the substrate surface.

FIGS. 2D and 2E illustrate respective suspended mono-crystalline structures 240 after annealing 130, according to some embodiments of the present invention. After annealing 130, the fused together widened solid portions form a suspended mono-crystalline structure 240. In the embodiment illustrated in FIG. 2D, cavities 250 are present below the suspended mono-crystalline structure 240. Specifically as illustrated in FIG. 2D, a solid or continuous heteroepitaxial structure 240 suspended above a plurality of rounded cavities 250 has been formed by annealing 130. The rounded cavities 250 may be roughly spherical when the 3-D structure comprises holes, for example. The rounded cavities 250 may be roughly tubular or cylindrical, for example, when the 3-D structure 230 comprises trenches.

In FIG. 2E, in addition to the solid or continuous suspended mono-crystalline structure 240 being formed after annealing 130, the adjacent cavities 250 below the heteroepitaxial structure 240 have fused together to produce a continuous, larger cavity 250 separating the suspended mono-crystalline structure 240 from the substrate 220. The suspended mono-crystalline structure 240 also becomes larger when the underlying cavity 250 becomes larger (i.e., the suspended mono-crystalline structure 240 generally spans a greater lateral distance). Adjacent cavities 250 may fuse as material in pillars from the 3-D structure 230 that initially separated the cavities 250 migrates during annealing up into the suspended mono-crystalline structure 240, for example. Effectively, the pillars ‘pinch off’ and are incorporated in the suspended mono-crystalline structure 240, according to some embodiments. In some embodiments, a portion of the pillars may migrate downwards and be incorporated into a bottom of the cavity 250. Whether or not adjacent cavities 250 fuse together to form a single cavity 250, as illustrated in FIG. 2E, or remain as a plurality of separate cavities 250, as illustrated in FIG. 2D, is a function of an initial configuration (e.g., spacing and relative sizes) of the elements in the 3-D structure 230 as well as a predetermined temperature and a predetermined time period employed during annealing 130.

The corners at intersections of the sidewalls and the roof or top wall of the cavity or cavities 250 are generally rounded by the annealing-induced surface migration. In particular, due to the tendency for the surface migration to seek a shape having a lower energy state, the corners of the cavity 250 affected by the surface migration have a finite radius of curvature that is determined by a size and spacing of the elements of the 3-D structure as well as characteristics of the annealing 130 that was performed (e.g., time period and temperature), as has already been discussed. The rounded corners produced by annealing-induced surface migration are unique and can readily be distinguished from corners produced in cavities by other means (e.g., removal of a sacrificial layer). Moreover, the sidewalls and the roof of the cavity 250 resulting from annealing 130, according to the present invention, generally are smoother at an atomic level than is achievable by any other means. In particular, surface migration not only rounds corners but also minimizes surface roughness in an attempt to reduce an energy state of the surface.

FIG. 3A illustrates a cross sectional view of a three dimensional (3-D) structure 230 formed 120 in the heteroepitaxial layer 210 illustrated in FIG. 2A, according to another embodiment of the present invention. FIG. 3B illustrates a suspended mono-crystalline structure 240 resulting from the 3-D structure 230 illustrated in FIG. 3A, according to an embodiment of the present invention. In particular, the 3-D structure 230 illustrated in FIG. 3A extends entirely through a thickness the heteroepitaxial layer 210 and into a surface portion of the underlying crystalline substrate 220. After annealing 130, the resultant suspended mono-crystalline structure 240 is supported on pillars 242. In particular, the suspended mono-crystalline structure 240 is suspended between the pillars 242. In some embodiments, the pillars 242 may comprise material from both the heteroepitaxial layer 210 and the underlying crystalline substrate 220, as illustrated by way of example. Further, as was described above, lattice defects 212 are largely removed from the suspended mono-crystalline structure 240 through surface migration and bulk diffusion as a result of the annealing 130. However, some lattice defects 212′ may remain adjacent to an interface between the underlying substrate 220 and the heteroepitaxial material in the pillars 242, as illustrated in FIG. 3B, by way of example.

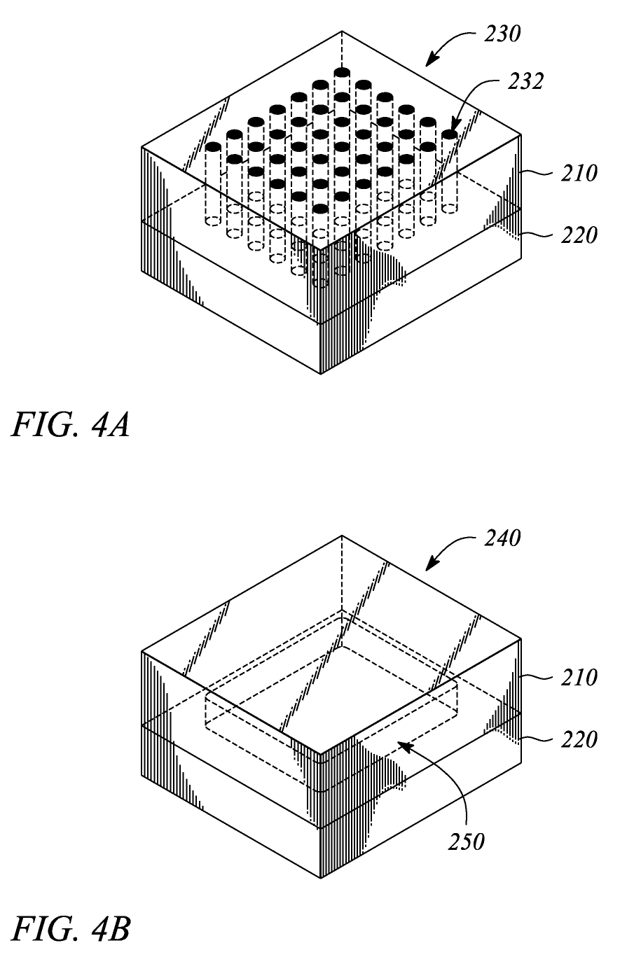

FIG. 4A illustrates a perspective view of a 3-D structure 230 formed 120 in a heteroepitaxial layer 210, according to an embodiment of the present invention. In particular, the 3-D structure 230 comprises a two dimensional array of holes 232. The holes 232 have a depth that is greater than a diameter of the holes. In some embodiments, a spacing of holes measured between adjacent edges of the holes may be similar to a diameter of the holes. FIG. 4B illustrates a perspective view of a suspended mono-crystalline structure 240 resulting from annealing 130 the 3-D structure 230 illustrated in FIG. 4A, according to an embodiment of the present invention. As illustrated, annealing-induced surface migration has resulted in a surface transformation that effectively closed the holes 232 at a top surface of the heteroepitaxial layer 210. Closing of the holes 232 has yielded a ‘plate-like’ or a two dimensional (2-D) suspended mono-crystalline structure 240, as illustrated. Further, a lower portion of adjacent ones of the holes have combined to produce a rectangular cavity 250 between the suspended mono-crystalline structure 240 and the substrate 220.

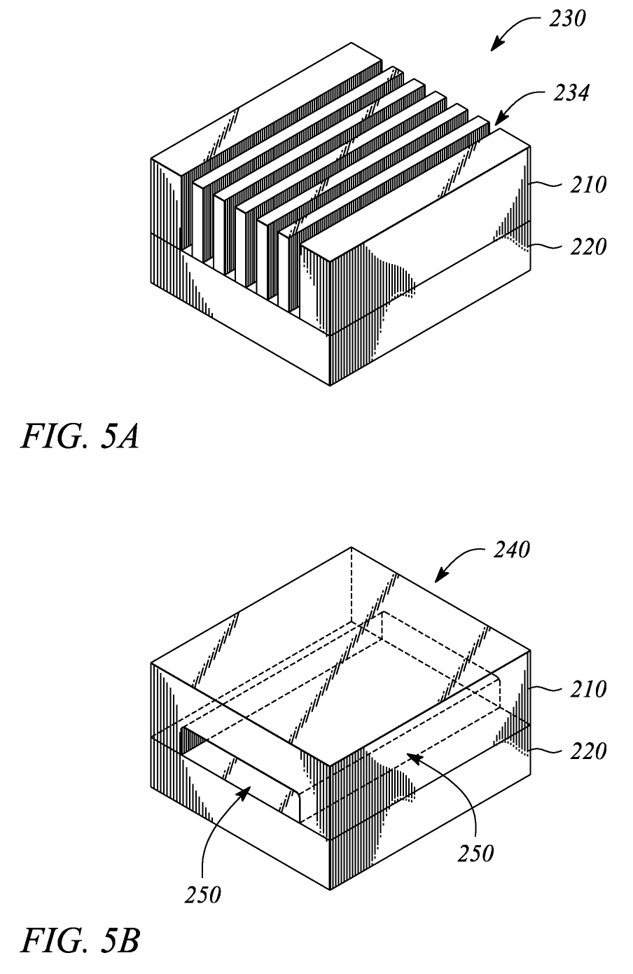

FIG. 5A illustrates a perspective view of a 3-D structure 230 formed 120 in a heteroepitaxial layer 210, according to another embodiment of the present invention. In particular, the 3-D structure 230 illustrated in FIG. 5A comprises a plurality of parallel trenches 234. FIG. 5B illustrates a perspective view of a suspended mono-crystalline structure 240 resulting from annealing 130 the 3-D structure 230 illustrated in FIG. 5A, according to an embodiment of the present invention. Specifically, FIG. 5B illustrates the suspended mono-crystalline structure 240 above a single rectangular cavity 250. As illustrated by way of example, the rectangular cavity 250 has openings at two ends. In some embodiments (not illustrated), the suspended mono-crystalline structure may be suspended above a plurality of tubular cavities. Such an embodiment may have a cross section similar to that illustrated in FIG. 2D, for example.

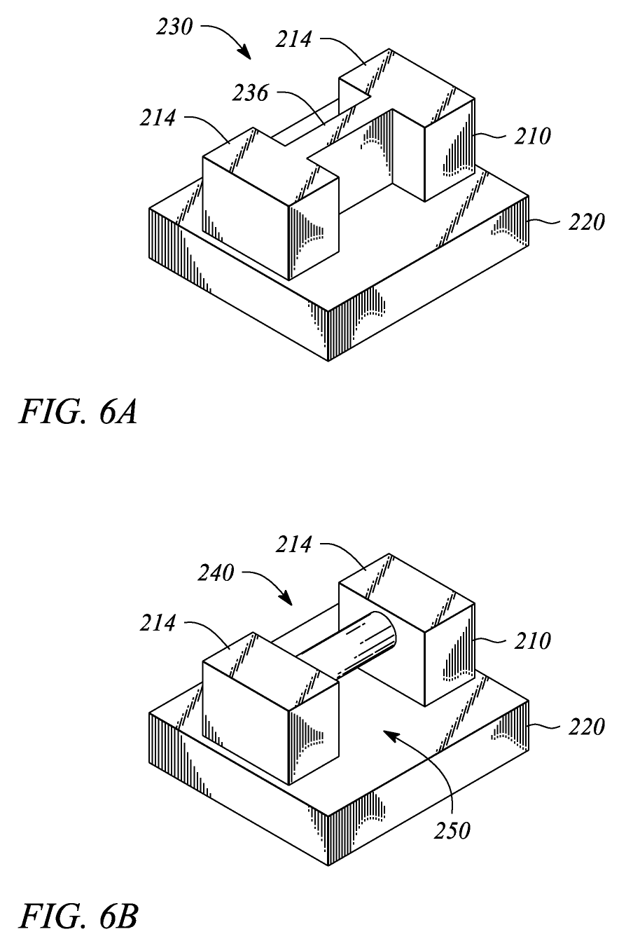

FIG. 6A illustrates a perspective view of a 3-D structure 230 formed 120 in a heteroepitaxial layer 210, according to another embodiment of the present invention. In particular, illustrated in FIG. 6A is an exemplary 3-D structure 230 comprising a narrow wall 236 connecting between two relatively wider, spaced apart blocks 214 of material formed from the heteroepitaxial layer 210. FIG. 6B illustrates a perspective view of a suspended mono-crystalline structure 240 resulting from annealing 130 the 3-D structure 230 illustrated in FIG. 6A, according to an embodiment of the present invention. Specifically, annealing-induced surface migration transforms the narrow wall 236 into a rod or bar shaped suspended mono-crystalline structure 240 that spans the space between the spaced apart blocks 214. The cavity 250 is a space that forms under the bar shaped suspended mono-crystalline structure 240 as a result of surface migration during annealing 130.

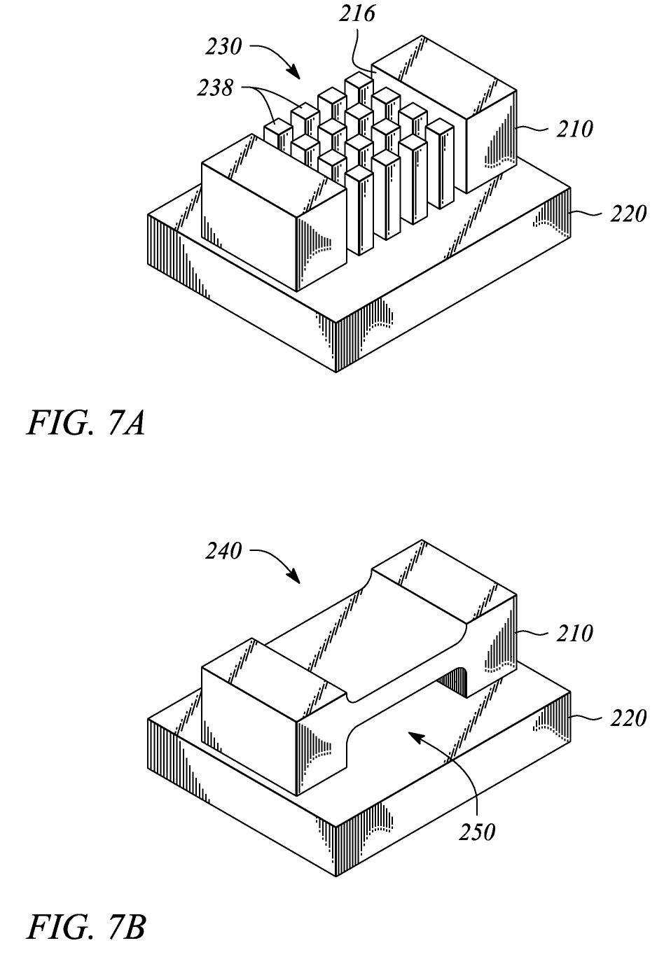

FIG. 7A illustrates a perspective view of a 3-D structure 230 formed 120 in a heteroepitaxial layer 210, according to another embodiment of the present invention. In particular, the 3-D structure 230 illustrated in FIG. 7A comprises an array of posts 238 formed 120 from the heteroepitaxial layer 210. The posts 238 extend up from a surface of the crystalline substrate 220. In some embodiments, the array of posts 238 may be bounded on one or more sides (two bounded sides are illustrated in FIG. 7A by way of example) by blocks or walls 216 of the heteroepitaxial layer 210, as illustrated. FIG. 7B illustrates a perspective view of a suspended mono-crystalline structure 240 resulting from annealing 130 the 3-D structure 230 illustrated in FIG. 7A, according to an embodiment of the present invention. A cavity 250 forms under the suspended heteropitaxial structure 240 during annealing as adjacent posts 238 fuse to one another due to surface migration. The blocks or walls 216 act to support the suspended mono-crystalline structure 240 when the posts pinch off during annealing 130.

Thus, there have been described embodiments of a semiconductor-on-nothing substrate and methods of fabricating a semiconductor-on-nothing substrate and a suspended mono-crystalline structure employing surface migration induced by annealing a 3-D structure in a heteroepitaxial layer. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A method of fabricating a suspended mono-crystalline structure, the method comprising:
providing a heteroepitaxial layer on a crystalline substrate;
forming a three dimensional (3-D) structure in the heteroepitaxial layer, the 3-D structure comprising high aspect ratio elements; and
annealing the 3-D structure to induce surface migration, the surface migration forming the suspended mono-crystalline structure above a cavity, the suspended mono-crystalline structure comprising a material of the heteroepitaxial layer,
wherein annealing is performed at a temperature below a melting point of the heteroepitaxial layer.

2. The method of fabricating of claim 1, wherein the 3-D structure comprises an array of holes, the holes extending toward the crystalline substrate from a surface of the heteroepitaxial layer opposite the crystalline substrate.

3. The method of fabricating of claim 2, wherein the array of holes comprises a two dimensional array in the heteroepitaxial layer and wherein the formed suspended mono-crystalline structure is a plate-like suspended mono-crystalline structure above a planar cavity having two lateral dimensions substantially parallel to a plane of the substrate.

4. The method of fabricating of claim 1, wherein the 3-D structure comprises a plurality of parallel trenches, the trenches extending toward the crystalline substrate from a surface of the heteroepitaxial layer opposite the crystalline substrate.

5. The method of fabricating of claim 1, wherein the 3-D structure comprises an array of posts located between a pair of walls formed from the heteroepitaxial layer, the posts extending from the substrate and wherein the suspended mono-crystalline structure comprises a planar bridge connected to the walls.

6. The method of fabricating of claim 1, wherein the 3-D structure comprises a pair of spaced apart blocks and a wall connecting between the pair of spaced apart blocks, the wall being narrower than the blocks, the suspended mono-crystalline structure being rod-shaped and wherein the cavity formed by annealing comprises a space between a the rod-shaped suspended mono-crystalline structure and the crystalline substrate.

7. The method of fabricating of claim 1, wherein the 3-D structure extends into a surface portion of the crystalline substrate, the surface portion being adjacent to the heteroepitaxial layer, the suspended mono-crystalline structure being supported by pillars.

8. The method of fabricating of claim 1, wherein the heteroepitaxial layer comprises a semiconductor.

9. The method of fabricating of claim 1, wherein the heteroepitaxial layer comprises germanium and the crystalline substrate comprises silicon.

10. A method of fabricating a suspended mono-crystalline structure, the method comprising:
providing a crystalline substrate, a material of the crystalline substrate having a first melting point;
growing on a surface of the crystalline substrate a heteroepitaxial layer comprising a semiconductor, the semiconductor having a second melting point that is lower than the first melting point;
forming a three dimensional (3-D) structure in the heteroepitaxial layer semiconductor;
inducing surface migration of the 3-D structure by annealing at a temperature below the second melting point, the surface migration producing the suspended mono-crystalline structure above a cavity, the suspended mono-crystalline structure comprising a single crystal of the heteroepitaxial layer semiconductor,
wherein the suspended mono-crystalline structure on the crystalline substrate is a portion of a semiconductor-on-nothing (SON) substrate.

11. The method of fabricating a SON substrate of claim 10, wherein the semiconductor comprises germanium, and wherein inducing surface migration is performed in a hydrogen ambient atmosphere at a temperature between about 650 degree Celsius and about 900 degrees Celsius.

12. The method of fabricating an SON substrate of claim 10, wherein the material of the crystalline substrate comprises silicon (Si), the suspended mono-crystalline structure having fewer lattice defects than the semiconductor heteroepitaxial layer.

13. The method of fabricating a SON substrate of claim 10, wherein forming the three dimensional structure comprises forming one or more of an array of holes, array of posts and a plurality of trenches in the heteroepitaxial layer semiconductor.

14. A semiconductor-on-nothing substrate comprising:
a crystalline substrate; and
a heteroepitaxial semiconductor layer on a surface of the crystalline substrate, the heteroepitaxial semiconductor layer having a melting point that is lower than a melting point of the crystalline substrate, the heteroepitaxial semiconductor layer comprising a suspended mono-crystalline structure above a cavity adjacent to the crystalline substrate, an intersection between a top wall of the cavity and a side wall of the cavity being rounded and exhibiting a finite radius of curvature,
wherein the suspended mono-crystalline structure comprises a single crystal of the heteroepitaxial semiconductor that has a lower lattice defect density than portions of the heteroepitaxial layer that are not suspended above the cavity.

15. The semiconductor-on-nothing substrate of claim 14, wherein the heteroepitaxial semiconductor layer comprises one of germanium (Ge) and gallium arsenide (GaAs) and the crystalline substrate comprises silicon (Si).
